(19) United States
(12) Patent Application Publication
(10) Pub. No.: US 2024/0027498 A1
(43) Pub. Date: Jan. 25, 2024

(54) CONTINUOUS ACQUISITION IN A TEST AND MEASUREMENT INSTRUMENT

(71) Applicant: Tektronix, Inc., Beaverton, OR (US)

(72) Inventor: Ronald Allan Brown, Portland, OR (US)

(73) Assignee: Tektronix, Inc., Beaverton, OR (US)

(21) Appl. No.: 18/355,296

(22) Filed: Jul. 19, 2023

Related U.S. Application Data
(60) Provisional application No. 63/391,681, filed on Jul. 22, 2022.

(51) Int. Cl. G01R 13/02

(52) U.S. Cl. CPC G01R 13/0272; G01R 13/0254

(57) ABSTRACT

A test and measurement instrument includes an input configured to accept an input signal from a Device Under Test, an acquisition memory handler structured to store the input signal as a series of digital samples in an acquisition memory, and a rasterizer structured to generate a histogram of the values of the digital samples prior to or simultaneously with the values being stored in the acquisition memory. Methods of generating a raster display from a series of digital samples from an input display are also described.

### CROSS-REFERENCE TO RELATED APPLICATIONS

This disclosure claims benefit of U.S. Provisional Application No. 63/391,681, titled “CONTINUOUS ACQUISITION IN A TEST AND MEASUREMENT INSTRUMENT,” filed on Jul. 22, 2022, the disclosure of which is incorporated herein by reference in its entirety.

### TECHNICAL FIELD

This disclosure relates to test and measurement instruments, and more particularly to circuits and methods for reducing dead time associated with processing acquired data in a test and measurement instrument such as an oscilloscope.

### BACKGROUND

In a system where a test and measurement device, such as a digital oscilloscope, measures a signal of interest from a device under test (DUT), the rate at which the signal is sampled is frequently faster than the processor can render on the display using ordinary graphics processing.

In conventional instruments, the input sample stream from the DUT is typically sub- divided into active and inactive subsets to support architectures where storing and rendering/analyzing sample data alternate in time. The result of the active/inactive subsets is that the measurement instrument is effectively blind to samples and potential trigger conditions from the DUT during the rendering/analysis time, while the input stream is being stored. Depending on the instrument architecture, this “dead” time can be significant, sometimes exceeding 99% of real time of receiving signals from the DUT.

The net result is that an oscilloscope might have a very high sample rate yet still have a low likelihood of capturing an anomalous event from the DUT that is of interest to a user.

Examples of the disclosure address these and other deficiencies of conventional devices.

### BRIEF DESCRIPTION OF THE DRAWINGS

FIG. 1 is a functional block diagram of a continuous acquisition test and measurement instrument according to examples of the disclosure.

FIGS. 2A and 2B are block diagrams illustrating functions performed by a histogram processor of the instrument of FIG. 1, according to examples of the disclosure.

FIG. 3 is a functional block diagram illustrating functions performed by the acquisition processor of FIG. 1, according to examples of the disclosure.

FIG. 4 is a functional block diagram illustrating functions performed by the histogram subsystem of FIG. 3, according to examples of the disclosure.

FIG. 5 is an example output screen generated by the test and measurement instrument having continuous acquisition according to examples of the disclosure.

### DESCRIPTION

Embodiments according to the disclosure construct time-consecutive, two-dimensional histograms based on every sample received by an oscilloscope from a DUT, which are then shown to the user in a display. The histograms are created independent of generating a sampled waveform from the DUT in acquisition memory of the instrument itself. Thus, the generated histograms capture and render every input signal sample captured from the DUT that has a chance of impacting the displayed waveform. In some embodiments, to increase performance, incoming samples are ignored if they are already represented in the visual rendering such that their presence is merely duplicative or won't change the final display shown to the user. To save resources, this determination to potentially ignore incoming samples, when expedient to do so, is made as early as possible in the sample pipeline.

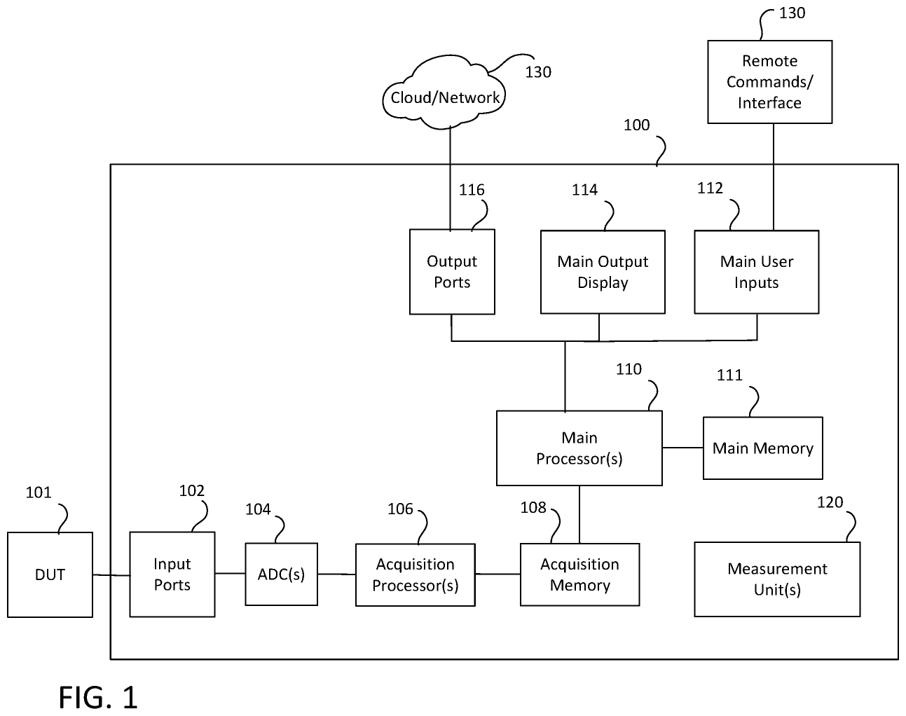

FIG. 1 is an example block diagram of a test and measurement instrument 100 having continuous acquisition according to some configurations of the disclosure. The test and measurement instrument 100 includes one or more ports 102, which may be any electrical or optical signaling medium. Ports 102 may include receivers, transmitters, and/or transceivers.

Each port 102 is a channel of the test and measurement instrument 100. In some embodiments the test and measurement instrument 100 includes 8, 16, or more separate ports. The test and measurement instrument 100 may couple to a Device Under Test (DUT) 101 through one or more ports 102. DUTs 101 that have multiple outputs may connect each output to the instrument 100 through multiple, independent ports 102.

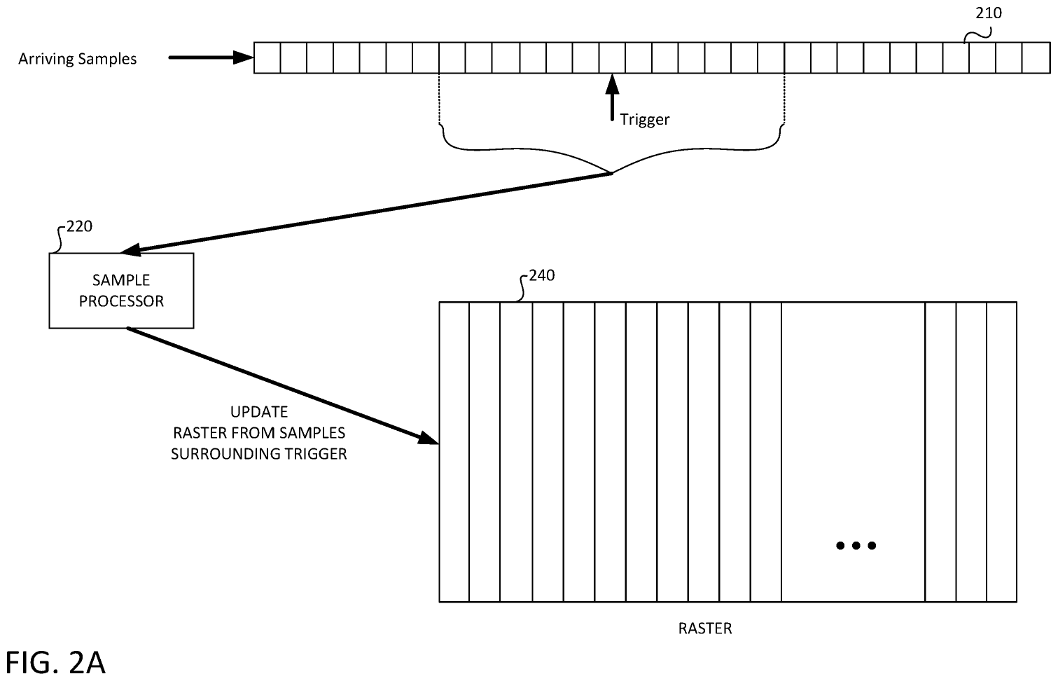

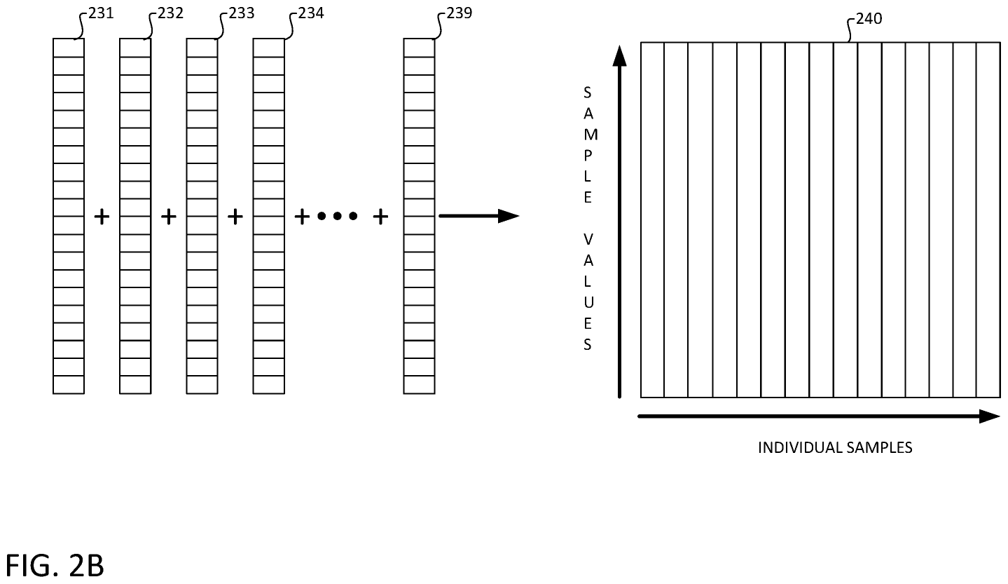

The input signals received at the ports 102 are then sent to one or more analog-to-digital converters (ADCs) 104. The one or more ADCs 104 convert an analog signal received through the one or more ports 102 to digital data that represents the input signal. The ADCs 104 have a sampling rate that is sufficient to sample the input signals with enough resolution to be usable by the instrument 100, and may be 8-bit, 12-bit, or higher resolution ADCs 104. The ADCs 104 may operate in an interleaved manner to sample all the incoming data, if required. The digitized signal output from the one or more ADCs 104 are processed by an acquisition processor 106 before being stored in an acquisition memory 108. Detailed description of the acquisition processor 106, and its main functions, are described in detail below with reference to FIGS. 2-6.

The acquisition memory 108 may be a relatively large, solid state memory that is structured to store large amounts of incoming data, as described in detail below. The acquisition memory 108 may be implemented as solid state memory, such as a solid-state disk drive(s). The acquisition memory 108 may be formed of Non-Volatile RAM (NVRAM). Other memory within the test and measurement instrument 100, such main processor memory 111, or other memory, may be implemented as processor cache, random access memory (RAM), read only memory (ROM), solid state memory, hard disk drive(s), or any other memory type. Memory acts as a medium for storing data, computer program products, and other instructions. In particular embodiments, the acquisition memory 108 may include 1 TB or more of memory having a 1 GB/s throughput rate. At such rates and capacities, a user may store 1000 seconds of incoming data in the acquisition memory 108. In some embodiments, data from the various memories of the instrument 100 may be output and/or stored in a cloud network 130.

One or more main processors 110 may be configured to execute instructions from main memory 111 and may perform any methods and/or associated steps indicated by such instructions.

Main user inputs 112 are coupled to the one or more processors 110. Main user inputs 112 may include a keyboard, mouse, touchscreen, and/or any other controls employable by a user to interact with a GUI on a main output display 114. In some embodiments the main user inputs 112 may be connected to or controlled by a remote interface 113, so that a user may control operation of the instrument 100 in a remote location physically away from the instrument. The display 114 may be a digital screen such as an LCD, or any other monitor to display waveforms, measurements, and other data to a user. In some embodiments, the main output display 114 is also located remote from the instrument 100.

One or more measurement units 120 are illustrated as being part of the instrument 100. These measurement units 120 perform the main functions of measuring parameters and other qualities of signals from the DUT being measured by the instrument 100. Typical measurements include measuring voltage, current, and power of input signals in the time domain, as well as measuring features of the input signals in the frequency domain. The measurement units 120 represent any measurements that are typically performed on test and measurement instruments.

While the components of the test and measurement instrument 100 are depicted as being integrated within test and measurement instrument 100, it will be appreciated by a person of ordinary skill in the art that any of these components can be external to the test and measurement instrument 100 and can be coupled to the test and measurement instrument 100 in any conventional manner (e.g., wired and/or wireless communication media and/or mechanisms). For example, in some examples, the main display 114 may be remote from the test and measurement instrument 100. In some embodiments a remote computer may connect to the instrument 100 through the remote interface 113 and cause the main display 114 to be shown on the display of the remote computer.

FIGS. 2A and 2B are block diagrams illustrating functions performed by a histogram processor according to embodiments of the disclosure. At a high level, the histogram processor generates histograms by capturing, in real time and at a full rate, data from samples received from the DUT. The captured histograms are then made available to a post-processing engine that transforms a histogram to an image suitable for display, and depending on the user's preferences, may be displayed on the main output display 114 or elsewhere by the instrument 100.

Referring to FIG. 2A, samples from the DUT, after being converted to digital form, are stored in a circular or ring buffer 210. The ring buffer 210 is longer than a record length that corresponds to a width of the screen that eventually displays an image of the incoming signal.

When a trigger condition occurs in the input signal, a set of individual data samples are retrieved from the ring buffer 210 and delivered to a sample processor 220. The number and location of individual data samples extracted from the ring buffer and sent to the sample processor depends on implementation details, but in general will include individual data samples that occurred before the trigger condition as well as individual data samples that occurred after the trigger condition. In other embodiments the data samples to be processed by the sample processor 220 are offset from the trigger itself. In such embodiments, the trigger could be an event that occurred in any part of the input signal, whether or not the triggering event is part of the individual data samples that are processed by the sample processor 220. Recall that individual samples remain in the ring buffer 210 until they are overwritten. So, when a triggering event occurs, a pre-determined number of samples that were stored in pre-determined locations of the ring buffer 210 relative to the triggering event are sent to the sample processor 220 to begin the operations of generating a two-dimensional raster display from the incoming samples. In one embodiment the number of samples retrieved from the ring buffer equals a power of two number, such as 2⁸, 2²⁰, 2³², etc., or any other power. In other embodiments the number of samples retrieved from the ring buffer does not need to be a power of two.

With reference to FIGS. 2A and 2B, a raster display 240 is composed of a number of columns, where each column corresponds to one of the samples in the set of samples gathered from the ring buffer 210. Each column is a histogram of values where each bin in the histogram is incremented each time a sample having the bin value is processed. In some embodiments a maximum value represents a value that renders maximum brightness or other characteristic in the final raster display. Histograms may therefore stop incrementing particular bins once they have reached this maximum value, as further accumulation does not improve the final raster display.

By assembling all of the individual histograms together, a two-dimensional raster 240 is generated that well represents, in graphic form, every sample that was processed by the sample processor 220 based on a triggering event. FIG. 2B illustrates columns 231-239 being assembled into the two-dimensional raster 240, but in practice the actual number of columns used to create the raster 240 may vary based on a number of factors. In the easiest case, the number of columns used to create the raster 240 exactly equals the number of samples sent to the sample processor 220 after a triggering event. But, in other cases, the number of samples may exceed the number of columns in the raster 240, or the number of samples may be less than the total number of columns in the raster 240. These special cases are explained in detail below. For the main example, however, assume that the number of samples from the ring buffer sent to the sample processor 220 after a triggering event equals the number of columns in the raster 240. In other words, the raster 240 of a waveform is essentially a two-dimensional histogram, where each column is an individual one-dimensional histogram of sample values that occurred at that relative time in the sample values from the ring buffer 210 with respect to the trigger time.

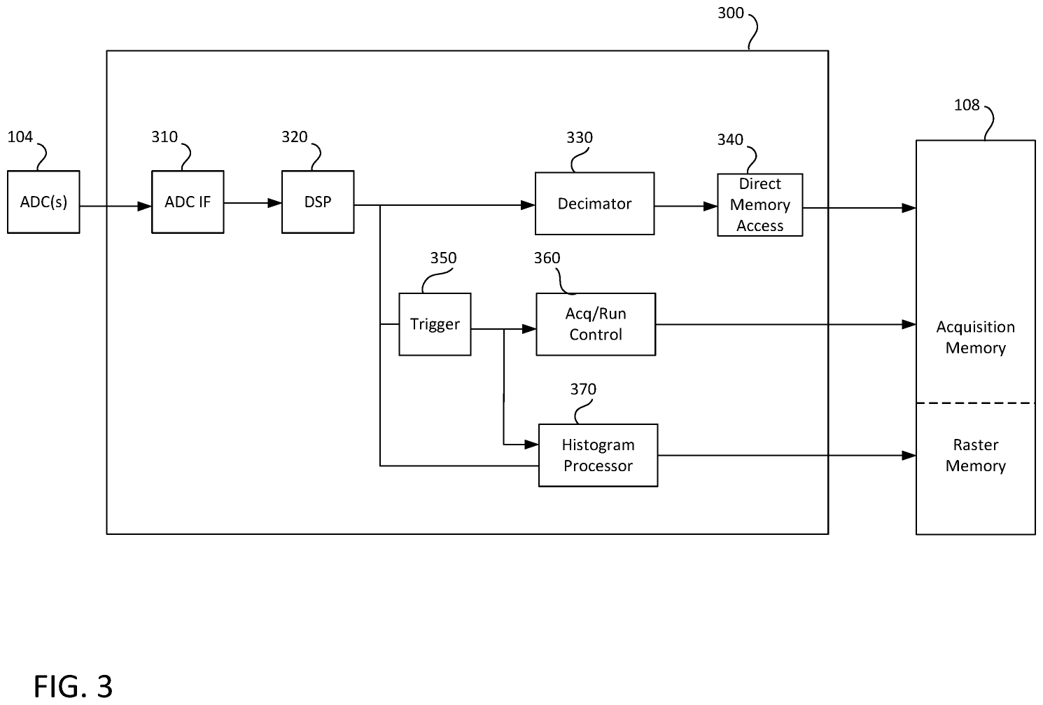

FIG. 3 is a block diagram showing details of an example embodiment of the acquisition processor. More specifically, an acquisition processor 300 of FIG. 3 may be an embodiment of the acquisition processor 106 of FIG. 1. Similar to the acquisition processor 106 of FIG. 1, the acquisition processor 300 of FIG. 3 is located between the ADCs 104 and the acquisition memory 108. Many components of the acquisition processor 300 are typical components found in standard acquisition processors, the functions of which are not described in detail. These include the ADC Intermediate Filter 310, Digital Signal Processor 320, decimator 330, Direct Memory Access 340, and Acq/Run control 360. The functions of the trigger processor 350 was described above and operates as an input to a histogram processor 370, which performs the majority of the operations described herein for continuous acquisition in a test and measurement instrument, according to embodiments of the disclosure.

Note that the histogram processor 370 in FIG. 3 creates a third path between the ADCs 104 (FIG. 1) to the acquisition memory, along with the path through the decimator 330 and Acq/Run control 360, both of which are conventional. The histogram processor 370 is new, however, and as described above, performs a function for continuous acquisition never included in previous instruments.

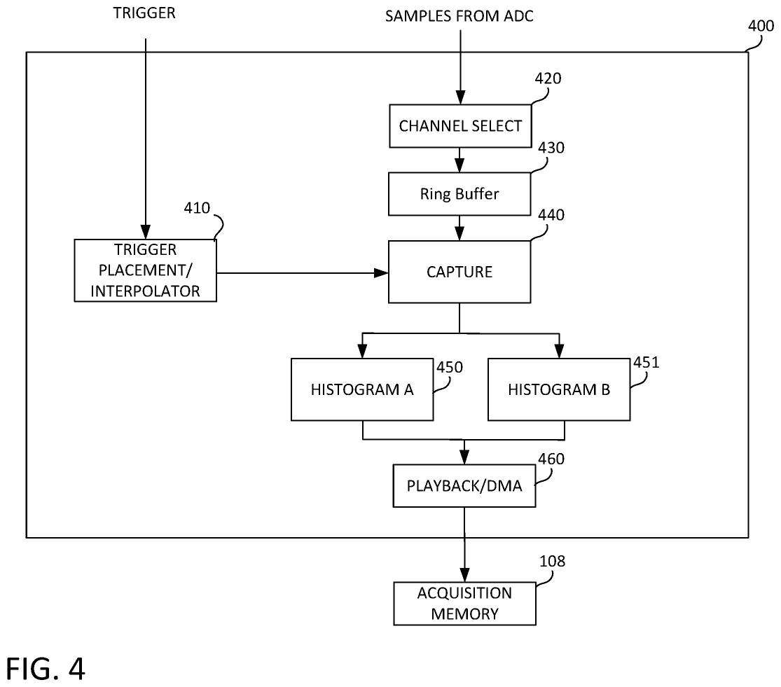

FIG. 4 is a functional block diagram of a histogram processor 400, which may be an embodiment of the histogram processor 370 of FIG. 3, according to examples of the disclosure.

Similar to FIG. 3, the histogram processor 400 receives input from both a trigger processor 250, as well as a direct path from output from the ADCs 104, which, in turn, originate from the DUT 101 (FIG. 1).

A trigger placement/interpolator 410 indicates that a trigger has been received and instructs a capture process 440 to generate a histogram from data stored in a ring buffer 430, as described above with reference to FIGS. 2A and 2B. In more detail, the trigger placement/interpolator 410 locates the sample in the ring buffer 430 that caused the trigger, and computes the exact point in time between that sample and the previous sample where the signal crossed a threshold as part of the trigger condition. A channel selector 420 specifies which channel the samples originate from. Depending on resource limitations, an instrument 100 could have anywhere from one histogram processor 400 shared by all channels of the instrument to a histogram processor 400 for each channel. When a histogram processor 400 is shared between two or more channels, signals from only one channel at a time are used to generate the raster display. Alternatively, when each channel includes its own dedicated histogram processor 400, each channel may include its own raster display generator operating in parallel with the other raster display generators for the other channels.

Not mentioned previously is that the typical embodiment of the histogram processor 400 includes two separate rasters, or as labeled in FIG. 4, histograms—histogram A 450 and histogram B 451. The reason for having two histograms 450, 451, is that it takes post-processing time from when the histogram is complete to when it is displayed for the user. For example, when the histogram 450 is ready to be displayed, the histogram processor 400 sends it to a playback facility, which may be a Direct Memory Access architecture 460 used to place the histogram 450 into the acquisition memory 108, or into other memory available to be accessed by the one or more processors 110 of the main instrument 100 (FIG. 1). From there, post-processing of the histogram 450 occurs, which may include adjusting horizontal and vertical dimensions, as described in further detail below. But, because this post-processing takes a non-zero amount of time, if there weren't a second histogram 451, then incoming samples would be missed while the first histogram 450 is being transferred to the acquisition memory 108 and reset/cleared to be able to use again. Instead, in a system with two histograms 450, 451, the histogram processor 400 immediately switches to the second histogram 451 as the first histogram 450 is being transferred to the acquisition memory 108, or other memory accessible by the main instrument 100 for view processing. Then, when the second histogram 451 is ready for viewing, the second histogram 451 is transferred to the acquisition memory 108 and the histogram processor 400 immediately switches back to filling the first histogram 450 with new sample data, with no input data being missed. In other words, based on the trigger condition, the input data from the DUT is captured in either the first histogram 450 or the second histogram 451. And it is possible that the trigger condition is always met, so that instruments according to the disclosure are capable of capturing all of the data originating from the DUT, without ever missing any of the input data.

Note that it is possible to implement the herein described method of continuous acquisition and display with only a single histogram in the histogram processor, which would decrease by half the histogram memory resources, while still reaching a fairly high live time ratio. In this scenario, the dead time of the oscilloscope becomes the time needed to transfer the single histogram to another memory location for post-processing, and to then reset it.

A post-processing transformation prior to showing one of the histograms 450, 451 on a display, such as the display 114 of FIG. 1, may be used to control parameters like colors of the waveform produced by the histogram or stretching the view to fit a specific display window. Other features such as intensity leveling and persistence may also be performed.

There is some flexibility in the selection of histogram width, but some hardware implementations fix the histogram width at a particular size. In general, the width of the histogram is typically chosen to be equal or similar to the display width. In a situation where the displayed width is variable, the histogram, or raster, could be widened, or stretched. For ratios near 1:1, a fairly simple horizontal scaling may be used without significant degradation.

The histogram height is a function of the number of bits in the input sample. Each additional sample bit doubles the necessary memory. Once the design complexity versus image quality trade-off is settled, different display area sizes may dictate that the vertical direction of the raster be elongated, particularly to account for different display area sizes. Depending on the bit depth, there might be more significant scaling needed in the vertical direction, which could result in an image that would appear more smeared than if each waveform were individually plotted.

Recall from above that, in the simplest embodiment, the number of columns in the raster exactly matches the number of samples gathered after a triggering event, but the number of columns may be more or fewer than the number of samples processed at one time. To account for different intended display widths, embodiments according to the disclosure account for cases where the samples are not placed into columns at a 1:1 ratio. For cases where the number of samples per column is less than 1, referred to as the underrepresented case, the histogram processor indexes across multiple columns per sample. For cases where the number of samples per column is greater than 1, referred to as the overrepresented case, the histogram processor skips samples by decimation.

In the underrepresented case, if there is sub-sample placement information available from analysis of the trigger condition, such as interpolation using the samples around an edge crossing, it is possible to use that sub-sample placement information to select the subset of columns to be filled. If sub-sample placement information is not available from the trigger type, then only a sub-set of columns will contain histogram data. Also, in this underrepresented case, the histogram might not be balanced. In this case, a leveling function could be applied to make all columns equal intensity. In some cases, the histogram might simply have a number of zero columns. One approach to account for columns holding zero data would be to fill in the missing columns using an approach derived from image morphing. To fill a gap between two filled histogram columns, the post-processing engine would locate the peaks within each histogram, map them to locate transform vectors, and re-create intermediate histograms through interpolation of location along the vectors, as well as intensity. This first-order approach would have artifacts for some conditions. It would be possible to take into account more than the two adjacent histograms, and look also at the vectors from standard deviation and histogram boundaries for directional guidance.

Further, in the underrepresented cases, some embodiments include “hit” counters for sub-sample offsets to be identified and institute some mitigations. These mitigations include introducing a small holdoff to break aliasing, as well as post-processing to re-create missing columns from neighbors. Yet other embodiments include using a placement “fuzzing” register to add horizontal blur to make the line generated by the raster display appear more continuous. Further embodiments of mitigating the condition of a discontinuous line caused by adjacent histograms having dissimilar values may include intensity leveling or morphing from adjacent columns, for example.

The underrepresented case may be used for equivalent time rendering in an instrument, where samples are placed into the histogram at the relevant time they were sampled with respect to the trigger position, based on an estimation of the sub-sample location of the trigger condition. Not all trigger modes result in sub-sample placement information, in which case samples are placed as if the condition occurred at the midpoint between samples, and equivalent time placement will not result in a continuous line.

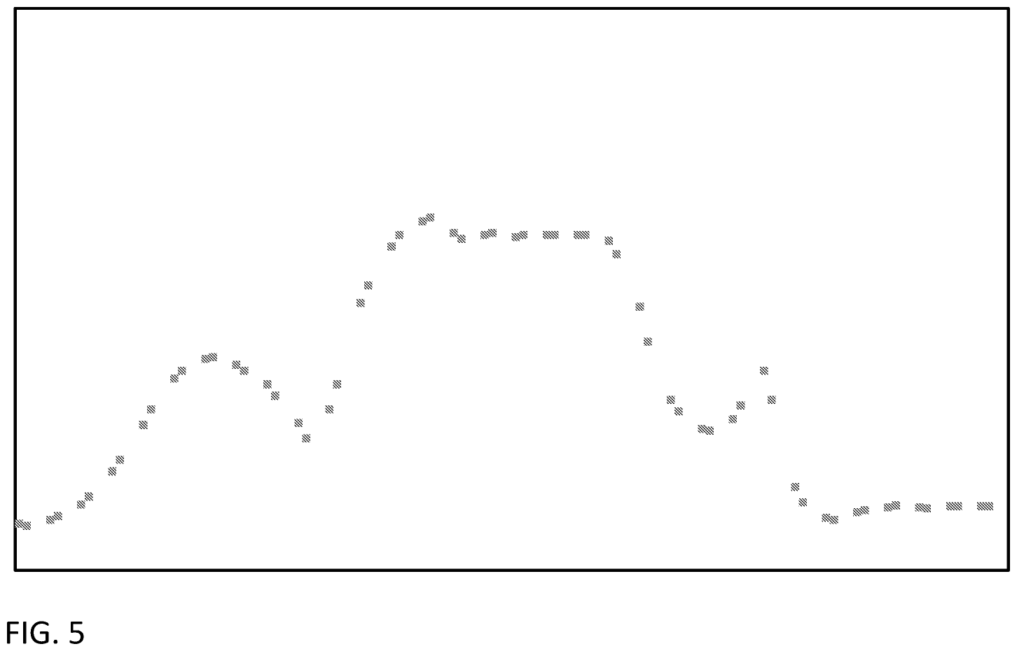

FIG. 5 is a diagram of an output display showing a conceptual example of a waveform that is sampled twice into the same raster, with different sub-sample references that result in different placement alignments within the raster. The two records are shown in different shades of grey. Although FIG. 5 illustrates only two sample sets in the illustrated raster, for clarity, in practice each raster typically includes many sample sets, on the order of thousands, tens of thousands, or millions of sample sets used to generate a single display. As additional records are integrated into the histogram with various offsets, the histogram will usually fill in the missing pieces so that the resulting line of the display appears continuous. However, there are cases, such as clean waveforms at frequencies harmonious with the sample rate, where this breaks down.

Within the design, this mode is referred to as super-rate. In super-rate mode, the record length is shorter than the standard histogram width by the under-representation ratio, and the samples are placed based on the phase that was determined from the trigger sub-sample position, and intervals of the super-rate factor.

Most digital oscilloscopes implement a notion of persistence—maintaining a reducing-intensity version of a previous raster over some period of decay time. This function could be achieved before or after other transformations, by a decayed version of the previous histogram with the next one, or similarly for the post-transformation display image.

According to an implemented example embodiment, a raster was generated having 1024 histogram columns and 256 bins per column. The source samples are 8 bits (2⁸=256), and the display is 1280 columns wide, but further includes edge UI elements. The internal memory in the histogram processor may be implemented using memory in an FPGA. In some embodiments, the entire histogram processor, such as the acquisition processor 300 of FIG. 3 is implemented in one or more FPGAs. A second example embodiment includes 2048 histogram columns and 1024 bins per column, which may have additional memory requirements compared to the example immediately above.

To select the bit depth, an important consideration is to determine how many distinct levels can be shown for a single pixel on the display. For example, for a monochrome image, the present display limit on a typical instrument 100 is 8 bits, and even within that range of 256 values, some are not useful, as they are too close to the background color (black) for the human eye to discern. Also, if a colorized waveform is generated from the histogram data, 24 bits/pixel may be used, for example.

By doubling some of the hardware resources, in some embodiments, it would be possible to run two raster extractions in parallel, thus approaching “200% live”, in the sense that some samples could impact the raster twice. With sufficient resources, even higher rates may be achieved. The benefit of operating beyond 100% live is the ability to visualize more instances of a trigger condition stacked at the same horizontal location, even if the condition is also visible on the left or right edges of the screen.

To support waveform persistence at capture time, the raster not presently in use could be reset in different ways after being copied to the acquisition memory. A basic no-hardware-persistence model would zero the histogram prior to using it again for sample storage. Alternately, the histogram bins could be scaled (reduced by a percentage), to simulate an effect like phosphor fade. One disadvantage to this technique is that the source is not the most-recent buffer, and the effect could be flickering of anomalous events. Depending on the display update rate, this might or might not be detectable by the human eye. Or if a single histogram implementation (not 100% live) is desired, the flicker artifact would not be present.

According to some embodiments of the disclosure, a user interface may display both the full rate raster, and a normally captured one, and permit fine-tuning of a complex trigger aimed at triggering on the spurious behavior. This requires careful crafting of the trigger engine to support both a simple trigger used for the full-rate capture and the more complex one a user is tuning.

Aspects of the disclosure may operate on particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

### EXAMPLES

Illustrative examples of the disclosed technologies are provided below. An embodiment of the technologies may include one or more, and any combination of, the examples described below.

Example 1 is a test and measurement instrument, including an input configured to accept an input signal from a Device Under Test, an acquisition memory handler structured to store the input signal as a series of digital samples in an acquisition memory, and a rasterizer structured to generate a histogram of values of the digital samples prior to or simultaneously with the values being stored in the acquisition memory.

Example 2 is a test and measurement instrument according to Example 1, further comprising a raster memory, and in which the histogram is stored in the raster memory.

Example 3 is a test and measurement instrument according to any preceding Example, in which the series of digital samples is stored in the acquisition memory and the histogram is stored in the raster memory simultaneously.

Example 4 is a test and measurement instrument according to any preceding Example, in which the rasterizer is structured to generate the histogram based on a trigger result.

Example 5 is a test and measurement instrument according to Example 4, further comprising a ring buffer to temporarily store the series of digital samples, and in which the values of the digital samples stored in the histogram are offset in the ring buffer from the trigger result.

Example 6 is a test and measurement instrument according to Example 5,in which a number of samples in the series of digital samples is less than a number of columns in the histogram, and in which the placement of the series of digital samples in the histogram is dependent on a trigger sub-sample position.

Example 7 is a test and measurement instrument according to any preceding Example, in which the rasterizer is structured to generate the histogram for up to all of the series of digital samples.

Example 8 is a test and measurement instrument according to any preceding Example, in which the histogram is used to generate a raster display, and in which particular of the series of digital samples that would not affect the appearance of the raster display are not represented in the histogram.

Example 9 is a test and measurement instrument according to any preceding Example, in which the histogram is two-dimensional.

Example 10 is a test and measurement instrument including an input for accepting an input signal from a Device Under Test (DUT) and storing the input signal in a ring buffer as a series of digital samples, a histogram processor configured to, during a raster building period: periodically select a portion of the series of digital samples based on a trigger condition, increment a corresponding bin value of a two-dimensional histogram for each selected digital sample in portion of the series of digital samples at least as fast as a rate at which the input samples are received from the DUT, and construct a raster formed of a plurality of histograms, in which the histogram processor is further configured to, during a raster output period, transfer the raster to a memory location in the test and measurement instrument, and further including a display driver structured to generate a raster waveform diagram on a display device based on the raster constructed by the histogram processor.

Example 11 is a test and measurement instrument according to Example 10, further including a second display driver structured to generate a second waveform diagram on the display device based on the series of digital samples.

Example 12 is a test and measurement instrument according to Examples 10 or 11, further including a raster memory, and in which the raster is stored in the raster memory.

Example 13 is a test and measurement instrument according to any of the Examples 10 — 12, in which the series of digital samples are stored in an acquisition memory and the raster is stored in the raster memory simultaneously.

Example 14 is a test and measurement instrument according to any of the Examples 10 — 13, in which a number of samples in the portion of the series of digital samples is less than a number of columns in the histogram, and in which the placement of the series of digital samples in the histogram is dependent on a trigger sub-sample position.

Example 15 is a method in a test and measurement instrument, including generating a series of digital samples from an input signal, storing the series of digital samples in a ring buffer, retrieving at least some of the series of digital samples from the ring buffer based on a trigger condition, generating a histogram from the at least some of the series of digital samples, generating a raster display from the histogram, and simultaneously storing the series of digital samples in an acquisition memory and storing the raster display in a raster memory.

Example 16 is a method according to Example 15, in which retrieving the at least some of the series of digital samples is based on an offset to a location of the trigger.

Example 17 is a method according to Example 16, in which generating the histogram includes populating the histogram with a number of samples that is less than a number of columns in the histogram, and in which the placement of the series of digital samples in the histogram is dependent on a trigger sub-sample position.

Example 18 is a method according to any preceding Example methods, in which the raster display is generated for up to all of the series of digital samples.

Example 19 is a method according to any preceding Example methods, further comprising displaying the raster display on the test and measurement instrument.

Example 20 is a method according to Example 19, further comprising displaying a waveform display from the series of digital samples, the waveform display separate from the raster display.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

What is claimed is:

1. A test and measurement instrument, comprising:
an input configured to accept an input signal from a Device Under Test;
an acquisition memory handler structured to store the input signal as a series of digital samples in an acquisition memory; and
a rasterizer structured to generate a histogram of values of the digital samples prior to or simultaneously with the values being stored in the acquisition memory.

2. The test and measurement instrument of claim 1, further comprising a raster memory, and in which the histogram is stored in the raster memory.

3. The test and measurement instrument of claim 1, in which the series of digital samples is stored in the acquisition memory and the histogram is stored in the raster memory simultaneously.

4. The test and measurement instrument of claim 1, in which the rasterizer is structured to generate the histogram based on a trigger result.

5. The test and measurement instrument of claim 4, further comprising a ring buffer to temporarily store the series of digital samples, and in which the values of the digital samples stored in the histogram are offset in the ring buffer from the trigger result.

6. The test and measurement instrument of claim 5, in which a number of samples in the series of digital samples is less than a number of columns in the histogram, and in which the placement of the series of digital samples in the histogram is dependent on a trigger sub-sample position.

7. The test and measurement instrument of claim 1, in which the rasterizer is structured to generate the histogram from up to all of the series of digital samples.

8. The test and measurement instrument of claim 1, in which the histogram is used to generate a raster display, and in which particular of the series of digital samples that would not affect the appearance of the raster display are not represented in the histogram.

9. The test and measurement instrument of claim 1, in which the histogram is two-dimensional.

10. A test and measurement instrument, comprising:
an input for accepting an input signal from a Device Under Test (DUT) and storing the input signal in a ring buffer as a series of digital samples;
a histogram processor configured to, during a raster building period:
periodically select a portion of the series of digital samples based on a trigger condition,
increment a corresponding bin value of a two-dimensional histogram for each selected digital sample in portion of the series of digital samples at least as fast as a rate at which the input samples are received from the DUT, and
construct a raster formed of a plurality of histograms;
the histogram processor further configured to, during a raster output period, transfer the raster to a memory location in the test and measurement instrument; and
a display driver structured to generate a raster waveform diagram on a display device based on the raster constructed by the histogram processor.

11. The test and measurement instrument of claim 10, further including a second display driver structured to generate a second waveform diagram on the display device based on the series of digital samples.

12. The test and measurement instrument of claim 10, further comprising a raster memory, and in which the raster is stored in the raster memory.

13. The test and measurement instrument of claim 10, in which the series of digital samples are stored in an acquisition memory and the raster is stored in the raster memory simultaneously.

14. The test and measurement instrument of claim 10, in which a number of samples in the portion of the series of digital samples is less than a number of columns in the histogram, and in which the placement of the series of digital samples in the histogram is dependent on a trigger sub-sample position.

15. A method in a test and measurement instrument, comprising:
generating a series of digital samples from an input signal;
storing the series of digital samples in a ring buffer;
retrieving at least some of the series of digital samples from the ring buffer based on a trigger condition;
generating a histogram from the at least some of the series of digital samples;
generating a raster display from the histogram; and
simultaneously storing the series of digital samples in an acquisition memory and storing the raster display in a raster memory.

16. The method of claim 15, in which retrieving the at least some of the series of digital samples is based on an offset to a location of the trigger.

17. The method of claim 16, in which generating the histogram includes populating the histogram with a number of samples that is less than a number of columns in the histogram, and in which the placement of the series of digital samples in the histogram is dependent on a trigger sub-sample position.

18. The method of claim 15, in which the raster display is generated for up to all of the series of digital samples.

19. The method of claim 15, further comprising displaying the raster display on the test and measurement instrument.

20. The method of claim 19, further comprising displaying a waveform display from the series of digital samples, the waveform display separate from the raster display.
